(19) United States
(12) Patent Application Publication
(10) Pub. No.: US 2025/0167099 A1
(43) Pub. Date: May 22, 2025

(54) SEMICONDUCTOR DEVICE AND METHOD FOR MANUFACTURING THEREOF

(71) Applicant: FUJI ELECTRIC CO., LTD., Kawasaki-shi (JP)

(72) Inventor: Hayato NAKANO, Kofu-city (JP)

(73) Assignee: FUJI ELECTRIC CO., LTD., Kawasaki-shi (JP)

(21) Appl. No.: 18/894,468

(22) Filed: Sep. 24, 2024

(30) Foreign Application Priority Data
Nov. 16, 2023 (JP) 2023-194880

(51) Int. Cl. H01L 23/498; H01L 21/48; H01L 23/15; H01L 23/373

(52) U.S. Cl. CPC H01L 23/49844; H01L 21/4853; H01L 23/3735; H01L 23/49811; H01L 23/15; H01L 23/49866

(57) ABSTRACT

A semiconductor device includes: a metal layer including a top surface having a hole including a recessed-projecting portion constituted by recesses and projections continuously formed on a surface of the hole; and a terminal having one end inserted into the hole and extending upward from the top surface of the metal layer. A method for manufacturing a semiconductor device includes: preparing a metal layer having a hole including a recessed-projecting portion constituted by recesses and projections continuously formed on a surface of the hole; preparing a terminal; and joining the terminal to the metal layer by inserting one end of the terminal into the hole.

### CROSS-REFERENCE TO RELATED APPLICATION

This application claims benefit of priority under 35 USC 119 based on Japanese Patent Application No. 2023-194880 filed on Nov. 16, 2023, the entire contents of which are incorporated by reference herein.

### 1. FIELD OF THE INVENTION

The present disclosure relates to a semiconductor device and a method for manufacturing thereof.

### 2. DESCRIPTION OF THE RELATED ART

JP2019-161174A discloses that a hole into which a terminal provided in a metal plate on a circuit board is inserted has a reversed trapezoidal shape. JP2013-102112A discloses that a plating layer is provided on a press-fitting surface of a terminal. JP1997-283682A discloses that an engaging pin is press-fitted to a heat dissipation plate. JP2018-113326A discloses that a terminal block having a threaded hole is joined onto a circuit pattern. JP2014-175444A discloses that a connection terminal is inserted into a terminal insertion hole provided on a case. JP2019-506753A discloses that a press-fit pin may be used as a terminal.

JP2020-136369A discloses that a circular hole into which a pin portion is inserted is provided on a heat dissipation plate. JP2021-19064A discloses that a hollow member into which an external terminal is inserted is provided on a conductive layer. U.S. Pat. No. 8,563,364B2 discloses that a terminal (a contact pin) is joined to a metal plate of a circuit board by laser, an electron beam, resistance welding, spinning, friction, ultrasonic welding, or ball bonding. U.S. Pat. No. 8,586,420B2 discloses that a contact pin is press-fitted to a metal plate of a circuit board.

In a conventional semiconductor device, it is considered to join a metal layer of a conductive plate or the like of an insulating circuit board to a terminal by press-fitting the terminal to a hole provided in the metal layer.

However, a mechanism to hold the terminal is only a force caused by press-fitting, and therefore, the joining strength between the terminal and the metal layer is weak, and the terminal may fall out of the metal layer after long-term drive.

### SUMMARY OF THE INVENTION

In view of the above problem, an object of this disclosure is to provide a semiconductor device and a method for manufacturing thereof each of which can improve the joining strength between a terminal and a metal layer.

An aspect of the present disclosure inheres in a semiconductor device including: a metal layer including a top surface having a hole including a recessed-projecting portion constituted by recesses and projections continuously formed on a surface of the hole; and a terminal having one end inserted into the hole and extending upward from the top surface of the metal layer.

Another aspect of the present disclosure inheres in a method for manufacturing a semiconductor device including: preparing a metal layer having a hole including a recessed-projecting portion constituted by recesses and projections continuously formed on a surface of the hole; preparing a terminal; and joining the terminal to the metal layer by inserting one end of the terminal into the hole.

Further aspect of the present disclosure inheres in a method for manufacturing a semiconductor device including: preparing a metal layer having a hole; preparing a terminal including a recessed-projecting portion constituted by recesses and projections formed continuously on a surface of at least one end of the terminal; and joining the terminal to the metal layer by inserting, into the hole, the one end of the terminal including the recessed-projecting portion.

### BRIEF DESCRIPTION OF THE DRAWINGS

FIG. 1 is a sectional view illustrating an overall schematic configuration of a semiconductor device according to a first embodiment;

FIG. 2 is a sectional view illustrating a state of a joined portion for a terminal in the semiconductor device according to the first embodiment after the terminal is press-fitted to the joined portion;

FIG. 3 is a sectional view illustrating a state of the joined portion for the terminal of the semiconductor device according to the first embodiment before the terminal is press-fitted to the joined portion;

FIG. 4 is a plan view of a joined portion of a metal layer in the semiconductor device according to the first embodiment, which joins with the terminal;

FIG. 5 is a sectional view illustrating a state of a joined portion for a terminal in a semiconductor device according to a comparative example before the terminal is press-fitted to the joined portion;

FIG. 6 is a sectional view illustrating a state of the joined portion for the terminal in the semiconductor device according to the comparative example after the terminal is press-fitted to the joined portion;

FIG. 7 is a sectional view illustrating a state of a joined portion for a terminal in a semiconductor device according to a second embodiment after the terminal is press-fitted to the joined portion;

FIG. 8 is a sectional view illustrating a state of a joined portion for a terminal in a semiconductor device according to a third embodiment after the terminal is press-fitted to the joined portion;

FIG. 9 is a sectional view illustrating a state of a joined portion for a terminal in a semiconductor device according to a fourth embodiment before the terminal is press-fitted to the joined portion;

FIG. 10 is a sectional view illustrating a state of a joined portion for a terminal in a semiconductor device according to a fifth embodiment before the terminal is press-fitted to the joined portion;

FIG. 11 is a sectional view illustrating a state of a joined portion for a terminal in a semiconductor device according to a sixth embodiment before the terminal is press-fitted to the joined portion;

FIG. 12 is a sectional view illustrating a state of a joined portion for a terminal in a semiconductor device according to a seventh embodiment before the terminal is press-fitted to the joined portion;

FIG. 13 is a sectional view illustrating a state of a joined portion for a terminal in a semiconductor device according to an eighth embodiment before the terminal is press-fitted to the joined portion;

FIG. 14 is a sectional view illustrating a state of the joined portion for the terminal in the semiconductor device according to the eighth embodiment after the terminal is press-fitted to the joined portion;

FIG. 15 is a sectional view illustrating a state of a joined portion for a terminal in a semiconductor device according to a ninth embodiment before the terminal is press-fitted to the joined portion;

FIG. 16 is a sectional view illustrating a state of the joined portion for the terminal in the semiconductor device according to the ninth embodiment after the terminal is press-fitted to the joined portion;

FIG. 17 is a sectional view illustrating a state of a joined portion for a terminal in a semiconductor device according to a tenth embodiment after the terminal is press-fitted to the joined portion;

FIG. 18 is a sectional view illustrating a state of a joined portion for a terminal in a semiconductor device according to an eleventh embodiment after the terminal is press-fitted to the joined portion;

FIG. 19 is a sectional view of a terminal of a semiconductor device according to a twelfth embodiment, as viewed vertically to an axial direction of the terminal; and

FIG. 20 is a sectional view illustrating a state of a joined portion for a terminal in a semiconductor device according to a thirteenth embodiment after the terminal is press-fitted to the joined portion.

### DETAILED DESCRIPTION

With reference to the drawings, first to thirteenth embodiments of the present disclosure will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to thirteenth embodiments described below merely illustrate schematically devices and methods for specifying and giving shapes to the technical idea of the present disclosure, and the span of the technical idea is not limited to materials, shapes, structures, and relative positions of elements described herein.

Further, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

### First Embodiment

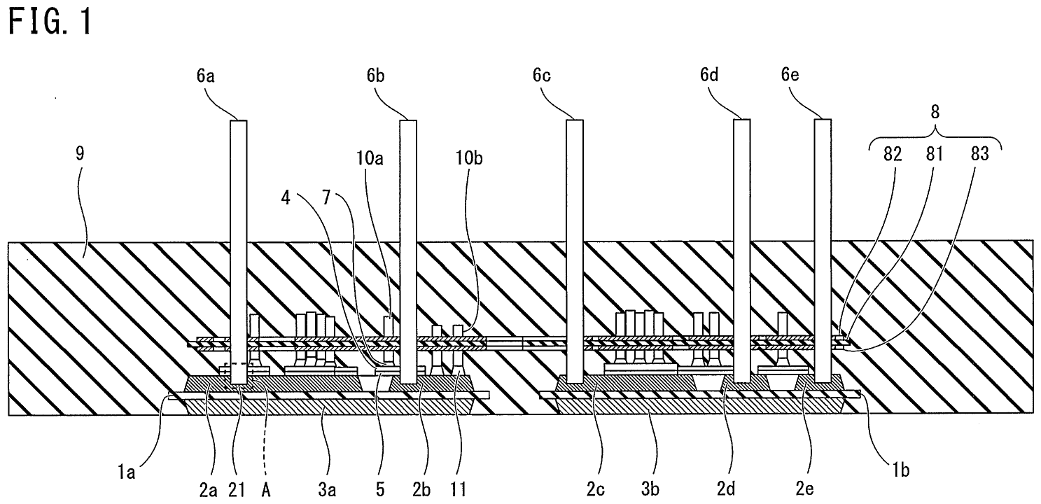

As a semiconductor device according to a first embodiment, a so-called 2-in -1 power semiconductor device including two serially-connected semiconductor modules, as illustrated in FIG. 1, will be described. The two serially-connected semiconductor modules are sealed with resin and electrically insulated from surroundings by a sealing resin 9.

A semiconductor module on the left side in FIG. 1 includes an insulating circuit board (1a, 2a, 2b, 3a), and terminals 6a, 6b provided on the insulating circuit board (1a, 2a, 2b, 3a) in a standing manner. A semiconductor module on the right side in FIG. 1 includes an insulating circuit board (1b, 2c to 2e, 3b), and terminals 6c to be provided on the insulating circuit board (1b, 2c to 2e, 3b) in a standing manner. A printed circuit board 8 is provided above the two insulating circuit boards (1a, 2a, 2b, 3a), (1b, 2c to 2e, 3b).

The insulating circuit boards (1a, 2a, 2b, 3a), (1b, 2c to 2e, 3b) may be direct copper bonding (DCB) substrates, active metal brazing (AMB) substrates, or the like, for example, and the following deals with a case where the insulating circuit boards (1a, 2a, 2b, 3a), (1b, 2c to 2e, 3b) are DCB substrates. The insulating circuit board (1a, 2a, 2b, 3a) includes an insulating substrate 1a, metal layers 2a, 2b as conductive plates provided on the top surface side of the insulating substrate 1a, and a metal layer 3a as a heat dissipation plate provided on the bottom surface side of the insulating substrate 1a. The insulating circuit board (1b, 2c to 2e, 3b) includes an insulating substrate 1b, metal layers 2c to 2e as conductive plates provided on the top surface side of the insulating substrate 1b, and a metal layer 3b as a heat dissipation plate provided on the bottom surface side of the insulating substrate 1b.

The insulating substrate 1a, 1b is constituted by a ceramics substrate made of aluminum oxide (Al₂O₃), aluminum nitride (AlN), silicon nitride (Si₃N₄), boron nitride (BN), or the like, or a resin insulating substrate made of a high polymer material or the like, for example. The metal layers 2a to 2e form circuit patterns. The metal layers 2a to 2e are not particularly limited in size, number, and arrangement position. The metal layers 2a to 2e and the metal layers 3a, 3b are made of a metal material such as copper (Cu), Cu alloy mainly containing Cu, aluminum (Al), or Al alloy mainly containing Al, for example.

A semiconductor element (semiconductor chip) 4 is joined to the top surface side of the metal layer 2a, 2c via a bonding material 5 such as solder. The semiconductor element 4 is constituted by, for example, a power semiconductor element such as an insulated gate bipolar transistor (IGBT), a field effect transistor (FET) such as a metal-oxide-semiconductor field-effect transistor (MOSFET), a static induction (SI) thyristor, a gate turnoff (GTO) thyristor, or a freewheeling diode (FWD). For example, in a case where the semiconductor element 4 is constituted by an IGBT, the semiconductor element 4 includes a first main electrode (collector electrode) on the bottom surface side, and a control electrode (gate electrode) and a second main electrode (emitter electrode) on the top surface side. The semiconductor element 4 is not particularly limited in type, size, number, and arrangement position. The semiconductor element 4 may be constituted by silicon (Si), for example, or may be constituted by a wideband gap semiconductor such as silicon carbide (SiC), gallium nitride (GaN), gallium arsenide (GaAs), gallium oxide (Ga₂O₃), or diamond (C).

A first implant pin 10a is provided on the semiconductor chip 4 via a bonding material 7 such as solder. The first implant pin 10a is electrically connected to the semiconductor element 4. A second implant pin 10b is provided in a region other than the semiconductor chip 4 on the metal layer 2a to 2e via a bonding material 11 such as solder. The second implant pin 10b is electrically connected to the metal layer 2a, 2b.

One end (lower end) of each of bar-shaped or pin-shaped terminals 6a to 6e is joined to the top surface side of its corresponding one of the metal layers 2a to 2e. The terminals 6a to 6e extend upward vertically to the top surfaces of the metal layers 2a to 2e. The other end (upper end) of each of the terminals 6a to 6e projects from the top surface of the sealing resin 9 and is exposed in such a manner as to be connectable with an external circuit (not illustrated).

In the semiconductor device according to the first embodiment, the terminals 6a to 6e function as external connection terminals. An output current, a measurement current, or the like flows through the terminals 6a to 6e between an external circuit (not illustrated) and the semiconductor element 4. For example, in a case of a semiconductor device in which an IGBT is used as the semiconductor chip 4 and a plurality of IGBTS is serially connected to each other in a forward direction, the terminal 6a can be used as an output terminal connected to a wiring line connecting an emitter electrode of one of the IGBTS to a collector electrode of another one of the IGBTS. The terminal 6b can be used as an emitter-side connection terminal electrically connected to the emitter electrode of the one of the IGBTS. The terminal 6c can be used as a collector-side connection terminal electrically connected to the collector electrode of the other one of the IGBTS. The terminals 6d, 6e can be used as a gate signal control terminal and an emitter signal terminal, respectively.

The printed circuit board 8 includes an insulating substrate 81, an upper circuit pattern 82 provided on the top surface of the insulating substrate 81, and a lower circuit pattern 83 provided on the bottom surface of the insulating substrate 81. The upper circuit pattern 82 and the lower circuit pattern 83 are conductive films made of metal or the like. The printed circuit board 8 has through-holes. The plurality of terminals 6a to 6e, the first implant pin 10a, and the second implant pin 10b are press-fitted to the through-holes on the printed circuit board 8 and supported (integrated). The printed circuit board 8 in which the plurality of terminals 6a to 6e, the first implant pin 10a, and the second implant pin 10b are integrated is also referred to as an “implant printed circuit board.”

The sealing resin 9 is made of a resin material such as epoxy resin, maleimide resin, or cyanate resin. Respective bottom surfaces of the metal layers 3a, 3b of the insulating circuit boards (1a, 2a, 2b, 3a), (1b, 2c to 2e, 3b) are exposed from the bottom surface of the sealing resin 9. A case (not illustrated) may be disposed outside the sealing resin 9.

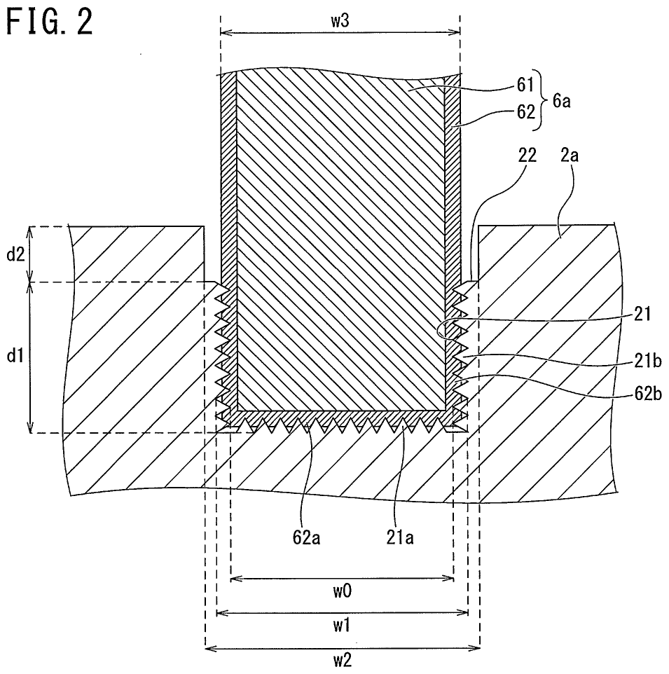

The following description mainly focuses on a joined portion between the terminal 6a and the metal layer 2a, the joined portion being surrounded by a region A indicated by a broken line in FIG. 1, but respective joined portions between the terminals 6b to 6e and the metal layers 2b to 2e also have the same configuration as that of the joined portion between the terminal 6a and the metal layer 2a. An enlarged section of the region A indicated by a broken line in FIG. 1 is illustrated in FIG. 2. In FIG. 2, the sealing resin 9 sealing the terminal 6b and the metal layer 2a is omitted.

As illustrated in FIG. 2, a hole (also referred to as a “recessed portion”) 21 is provided on the top surface of the metal layer 2a. The hole 21 is provided with a depth not allowing the hole 21 to penetrate through the metal layer 2a. Note that the hole 21 may penetrate through the metal layer 2a such that the top surface of the insulating substrate 1 is exposed in the hole 21. A step 22 is provided in an upper portion of the hole 21. A lower end as one end of the terminal 6a is inserted into (press-fitted to) the hole 21 such that the terminal 6a is joined to the metal layer 2a.

The hole 21 has a recessed-projecting portion (roughness) 21a, 21b having a surface on which recesses and projections are continuously formed intentionally by performing roughing. The recessed-projecting portion 21a is formed on the bottom surface of the hole 21, and the recessed-projecting portion 21b is provided on the side surface (side wall surface) of the hole 21. Note that both the recessed-projecting portions 21a, 21b may not be necessarily provided such that no recessed-projecting portion 21a is formed on the bottom surface of the hole 21 so that the bottom surface of the hole 21 is flat, and the recessed-projecting portion 21b is provided only on the side surface of the hole 21. Alternatively, no recessed-projecting portion 21b may be formed on the side surface of the hole 21 so that the side surface of the hole 21 is flat, and the recessed-projecting portion 21a may be provided only on the bottom surface of the hole 21. Note that the height and depth, the cycle, or the shape of the recesses and projections is not necessarily regular but is irregular, but they are illustrated in a regular shape in the following drawings for convenience.

An inner-side virtual inner peripheral surface in contact with the projections of the recessed-projecting portion 21b on the side surface of the hole 21 has a diameter w0, which is generally the same as a diameter w3 of a portion of the terminal 6a which is not inserted into the hole 21 and which is slightly smaller than the diameter w3. The diameter w0 is, for example, about 0.6 mm or more but 2.9 mm or less. An outer-side virtual inner peripheral surface in contact with the recesses of the recessed-projecting portion 21b on the side surface of the hole 21 has a diameter w1, which is larger than the diameter w0 and slightly larger than the diameter w3 of the portion of the terminal 6a which is not inserted into the hole 21. The diameter w3 of the portion of the terminal 6a which is not inserted into the hole 21 is, for example, about 1 mm or more but 2 mm or less. In the present specification, the “diameter of the hole 21” indicates the diameter w0 of the inner-side virtual inner peripheral surface in contact with the projections of the recessed-projecting portion 21b on the side surface of the hole 21.

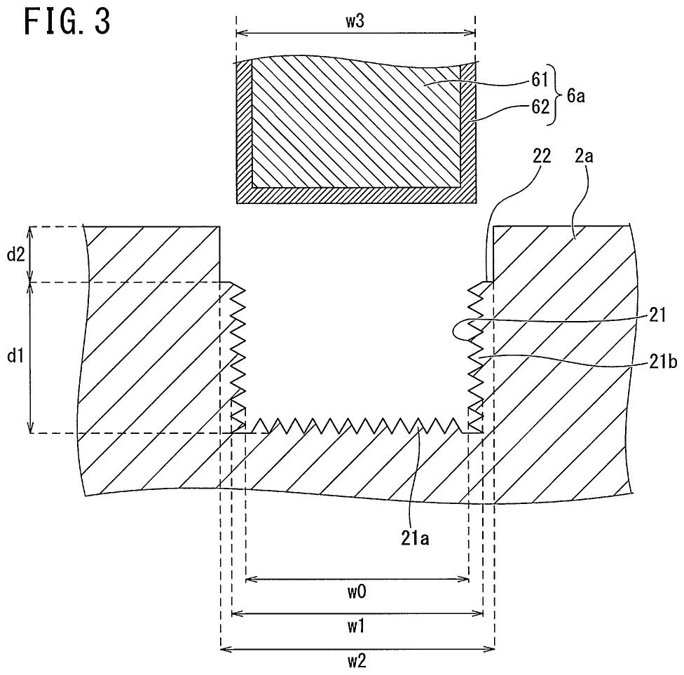

The diameter w3 of the portion of the terminal 6a which is not inserted into the hole 21 is a diameter of the terminal 6a before the terminal 6a is press-fitted to the hole 21. FIG. 3 illustrates a state before the terminal 6a is press-fitted to the hole 21 in a manufacturing process of the semiconductor device according to the first embodiment. In a sectional view of FIG. 3, the terminal 6a has a rectangular sectional shape having a lower end also provided with a plating layer 62 and uniformly has the diameter w3. When the terminal 6a illustrated in FIG. 3 is press-fitted to the hole 21, the terminal 6a is brought into the state illustrated in FIG. 2.

As illustrated in FIG. 2, the step 22 has a diameter w2 larger than the diameter w3 of the portion of the terminal 6a which is not inserted into the hole 21. The diameter w2 of the step 22 is, for example, about 1.1 mm or more but 2.3 mm or less. In the manufacturing process of the semiconductor device according to the first embodiment, the step 22 functions as a guide structure (guide) allowing the terminal 6a to be easily press-fitted to the hole 21 at the time when the terminal 6a is aligned and press-fitted to the hole 21 as illustrated in FIG. 3.

The metal layer 2a has a thickness of about 2 mm or more but 3 mm or less, for example. The hole 21 has a depth d1 that is about 3/5 or more but 4/5 or less of the thickness of the metal layer 2a, for example, and the depth d1 is about 1 mm or more but 2.5 mm or less, for example. The depth d1 of the hole 21 is a depth from the bottom surface of the step 22 to a virtual plane in contact with the recesses of the recessed-projecting portion 21a on the bottom surface of the hole 21. A depth d2 of the step 22 from the top surface of the metal layer 2a is about 0.2 mm or more but 0.5 mm or less, for example.

The terminal 6a includes a bar-shaped or pin-shaped main body 61, and the plating layer 62 provided on the surface side of the main body 61. Here, the main body 61 has a circular column shape. The main body 61 is not limited to a circular column shape and may have a polygonal column shape such as a square column shape, for example. The main body 61 is made of a metal material such as copper (Cu), Cu alloy mainly containing Cu, aluminum (Al), or Al alloy mainly containing Al, for example. The main body 61 may be made of the same material as the metal layer 2a or may be made of a material different from that of the metal layer 2a. For example, the main body 61 and the metal layer 2a may be both made of Cu.

The plating layer 62 is provided on at least an end surface and an outer peripheral surface of a portion of the main body 61 which is inserted into the hole 21. As illustrated in FIG. 2, the plating layer 62 may be provided on a portion of the main body 61 which is not inserted into the hole 21. Although not illustrated herein, the plating layer 62 may not be provided on the portion of the main body 61 which is not inserted into the hole 21 in such a manner as to expose the main body 61. The plating layer 62 has a thickness of about 5 μm or more but 200 μm or less, for example.

The plating layer 62 is made of a metal material such as tin (Sn) or nickel (Ni). In the first embodiment, the plating layer 62 is made of a material softer than the main body 61 and the metal layer 2a. The hardness (softness) of metal of the main body 61, the metal layer 2a, and the like can be expressed by Vickers hardness, for example, such that the metal is harder as the Vickers hardness is higher, and the metal is softer as the Vickers hardness is lower. For example, in a case where the main body 61 and the metal layer 2a are made of Cu, the plating layer 62 may be made of Sn, which is softer than Cu.

Since the diameter w0 of the hole 21 is generally the same as but slightly smaller than the diameter w3 of the portion of the terminal 6a which is not inserted into the hole 21, the plating layer 62 softer than the metal layer 2a, in the portion of the terminal 6a which is inserted into the hole 21, deforms to fit the recessed-projecting portions 21a, 21b of the hole 21. The plating layer 62 placed on the end surface of the terminal 6a includes a recessed-projecting portion 62a fitted (engaged) to the recessed-projecting portion 21a on the bottom surface of the hole 21. The plating layer 62 placed on the outer peripheral surface of the terminal 6a includes a recessed-projecting portion 62b fitted (engaged) to the recessed-projecting portion 21b on the side surface of the hole 21. Note that the recessed-projecting portions 21a, 21b of the hole 21 may have portions penetrating through the plating layer 62 and coming into contact with the main body 61 of the terminal 6a. The lower end of the terminal 6a may not be necessarily in contact with the bottom surface of the hole 21 and may be separated from the bottom surface of the hole 21.

The recessed-projecting portions 21a, 21b of the hole 21 are formed intentionally by performing roughing, and the recessed-projecting portions 21a, 21b of the hole 21 are different from recessed-projecting portions formed not intentionally but inevitably. The recessed-projecting portions 21a, 21b of the hole 21 are formed with recesses and projections larger (rougher) than those of the recessed-projecting portions formed not intentionally but inevitably, for example. Accordingly, the recessed-projecting portions 21a, 21b of the hole 21 can be distinguished from the recessed-projecting portions formed not intentionally but inevitably, based on the size (roughness) of the recesses and projections of the recessed-projecting portions 21a, 21b.

The arithmetic average roughness (Ra) of the recessed-projecting portions 21a, 21b of the hole 21 before the terminal 6a is press-fitted to the hole 21 is about 20 μm or more but 300 μm or less, for example, depending on the formation method of the recessed-projecting portions 21a, 21b. In a case where the recessed-projecting portions 21a, 21b are formed mechanically by a drill, a screw thread, or the like or the recessed-projecting portions 21a, 21b are formed by laser, the arithmetic average roughness (Ra) is about 20 μm or more but 180 μm or less and may be 100 μm or more but 200 μm or less, for example. In a case where the recessed-projecting portions 21a, 21b are formed by etching or the like, the arithmetic average roughness (Ra) is about 10 μm or more but 100 μm or less and may be 50 μm or more but 100 μm or less, for example.

In comparison with the state before the terminal 6a is press-fitted to the hole 21, the arithmetic average roughness (Ra) of the recessed-projecting portions 21a, 21b of the hole 21 after the terminal 6a is press-fitted to the hole 21 increases or decreases depending on the diameter w3 of the terminal 6a, the shape of the terminal 6a, whether or not the terminal 6a rotates at the time of press-fitting, or the like, and the arithmetic average roughness (Ra) is about 20 μm or more but 300 μm or less, for example. In a case where the recessed-projecting portions 21a, 21b are formed mechanically by a drill, a screw thread, or the like or the recessed-projecting portions 21a, 21b are formed by laser, the arithmetic average roughness (Ra) is about 20 μm or more but 180 μm or less and may be 100 μm or more but 200 μm or less, for example. In a case where the recessed-projecting portions 21a, 21b are formed by etching or the like, the arithmetic average roughness (Ra) is about 10 μm or more but 100 μm or less and may be 50 μm or more but 100 μm or less, for example.

In the state before or after the terminal 6a is press-fitted to the hole 21, the size (roughness) of the recessed-projecting portion 21a on the bottom surface of the hole 21 may be generally the same as the size (roughness) of the recessed-projecting portion 21b on the side surface of the hole 21. That is, the arithmetic average roughness (Ra) of the recessed-projecting portion 21a on the bottom surface of the hole 21 may be generally the same as the arithmetic average roughness (Ra) of the recessed-projecting portion 21b on the side surface of the hole 21. The size (roughness) of the recessed-projecting portion 21a on the bottom surface of the hole 21 may be larger or smaller than the size (roughness) of the recessed-projecting portion 21b on the side surface of the hole 21. That is, the arithmetic average roughness (Ra) of the recessed-projecting portion 21a on the bottom surface of the hole 21 may be larger or smaller than the arithmetic average roughness (Ra) of the recessed-projecting portion 21b on the side surface of the hole 21.

As a formation method of the recessed-projecting portion 21b on the side surface of the hole 21, the recessed-projecting portion 21b is formed on the side surface of the hole 21 while the hole 21 is formed by digging the metal layer 2a by a threaded drill, for example. Then, the drill is reversed to remove the drill from the metal layer 2a with the recessed-projecting portion 21b on the side surface of the hole 21 being left behind, and hereby, the recessed-projecting portion 21b on the side surface of the hole 21 can be formed mechanically. In a case where the recessed-projecting portion 21b is formed by the drill, the arithmetic average roughness (Ra) of the recessed-projecting portion 21b on the side surface of the hole 21 is about 20 μm or more but 300 μm or less, for example.

Further, as another formation method of the recessed-projecting portion 21b on the side surface of the hole 21, the hole 21 is formed by a drill, etching, or the like. Then, the side surface of the hole 21 may be roughened by diagonally applying laser on the side surface of the hole 21. The laser may be fiber laser, YAG laser, carbon dioxide (CO2) laser, or the like, for example. By adjusting application power, a spot diameter, or the like of the laser, the size (roughness) of the recessed-projecting portion 21b on the side surface of the hole 21 can be adjusted. In a case where the recessed-projecting portion 21b is formed by laser application, the arithmetic average roughness (Ra) of the recessed-projecting portion 21b on the side surface of the hole 21 is about 20 μm or more but 180 μm or less and may be about 100 μm or more but 200 μm or less, for example.

As another formation method of the recessed-projecting portion 21b on the side surface of the hole 21, the metal layer 2a may be made of metal particles (for example, copper particles) having a relatively small average particle diameter, and the recessed-projecting portion 21b on the side surface of the hole 21 may be formed while the hole 21 is formed by etching with the use of a mask. In this disclosure, the average particle diameter indicates a value of a particle diameter (D50) with a volume frequency of 50% which volume frequency is measured by laser diffractometry. By adjusting the size of metal particles constituting the metal layer 2a, the size (roughness) of the recessed-projecting portion 21b on the side surface of the hole 21 can be adjusted. In a case where the recessed-projecting portion 21b is formed by etching, the arithmetic average roughness (Ra) of the recessed-projecting portion 21b on the side surface of the hole 21 is about 10 μm or more but 100 μm or less and may be about 50 μm or more but 100 μm or less, for example.

As a formation method of the recessed-projecting portion 21a on the bottom surface of the hole 21, the hole 21 is formed by a drill, etching, or the like. Then, the bottom surface of the hole 21 may be roughened by vertically or diagonally applying laser on the bottom surface of the hole 21. The recessed-projecting portions 21a, 21b may be formed on the bottom surface and the side surface of the hole 21 at the same time by one laser application. By adjusting application power, a spot diameter, or the like of the laser, the size (roughness) of the recessed-projecting portion 21a on the bottom surface of the hole 21 can be adjusted. In a case where the recessed-projecting portion 21a is formed by laser application, the arithmetic average roughness (Ra) of the recessed-projecting portion 21a on the bottom surface of the hole 21 is about 20 μm or more but 150 μm or less.

As another formation method of the recessed-projecting portion 21a on the bottom surface of the hole 21, the metal layer 2a may be made of metal particles (for example, copper particles) having a relatively large average particle diameter, and the recessed-projecting portion 21a may be formed on the bottom surface of the hole 21 while the hole 21 is formed by etching with the use of a mask. By adjusting the size of the metal particles constituting the metal layer 2a, the degree (roughness) of the recessed-projecting portion 21a on the bottom surface of the hole 21 can be adjusted. The recessed-projecting portions 21a, 21b may be formed on the bottom surface and the side surface of the hole 21 at the same time by etching. In a case where the recessed-projecting portion 21a is formed by etching, the arithmetic average roughness (Ra) of the recessed-projecting portion 21a on the bottom surface of the hole 21 is about 10 μm or more but 100 μm or less and may be about 50 μm or more but 100 μm or less.

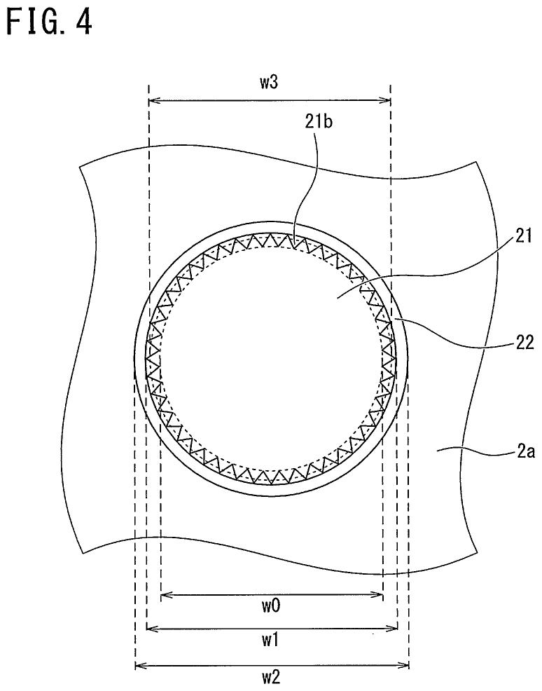

FIG. 4 is a plan view of the hole 21 and the step 22 of the metal layer 2a in the semiconductor device according to the first embodiment. For clearness in FIG. 4, the recessed-projecting portion 21a on the bottom surface of the hole 21 is omitted. The diameter w3 of the portion of the terminal 6a which is not inserted into the hole 21 is also schematically illustrated by a broken line. In a plan view of FIG. 4, the hole 21 has a circular plane pattern, for example. Note that the hole 21 may have a plane pattern in a polygonal shape such as a square shape. The step 22 has a circular plane pattern concentric with the hole 21, for example. The step 22 may have a plane pattern in a polygonal shape such as a square shape.

### <Manufacturing Method of Semiconductor Device>

With reference to FIG. 1 to FIG. 3, an example of a method for manufacturing (a method for assembling) the semiconductor device according to the first embodiment will be described below. Note that the following manufacturing method of the semiconductor device is one example, and it is needless to say that the semiconductor device is also achievable by various manufacturing methods including modifications other than the following manufacturing method, provided that the various manufacturing methods are achieved within the gist of claims.

First, the printed circuit board 8, the terminals 6a to 6e, the first implant pin 10a, and the second implant pin 10b illustrated in FIG. 1 are prepared. Then, the terminals 6a to 6e, the first implant pin 10a, and the second implant pin 10b are press-fitted to respective through-holes on the printed circuit board 8, and hereby, an implant printed circuit board is prepared.

Subsequently, the insulating circuit boards (1a, 2a, 2b, 3a), (1b, 2c to 2e, 3b) illustrated in FIG. 1 are prepared. The metal layers 2a, 2b are provided on the top surface side of the insulating circuit board (1a, 2a, 2b, 3a). The metal layers 2c to 2e are provided on the top surface side of the insulating circuit board (1b, 2c to 2e, 3b). As illustrated in FIG. 3, a portion of the metal layer 2a to which the terminal 6a is to be press-fitted is provided with the hole 21 and the step 22. The recessed-projecting portions 21a, 21b are intentionally formed on the bottom surface and the side surface of the hole 21. Respective portions of the metal layers 2b to 2e to which the terminals 6b to 6e are to be press-fitted, as illustrated in FIG. 1, also have the same configuration as that of the portion of the metal layer 2a to which the terminal 6a is to be press-fitted.

Subsequently, the semiconductor chip 4 is put on the top surfaces of the metal layers 2a to 2e of the insulating circuit boards (1a, 2a, 2b, 3a), (1b, 2c to 2e, 3b) via the bonding material 5. Subsequently, the bonding material 7 is provided on the top surface of the semiconductor chip 4, and the bonding material 11 is provided on the top surface of the metal layer 2b.

Subsequently, the implant printed circuit board is aligned to face the top surface sides of the insulating circuit boards (1a, 2a, 2b, 3a), (1b, 2c to 2e, 3b), and the terminals 6a to be are press-fitted to the metal layers 2a to 2e, respectively, and joined thereto by use of a pressure device.

Here, as illustrated in FIG. 3, in terms of the joined portion between the terminal 6a and the metal layer 2a, the terminal 6a is aligned to the hole 21 of the metal layer 2a. Then, as illustrated in FIG. 2, a lower end as one end of the terminal 6a is press-fitted to the hole 21 of the metal layer 2a, so that the lower end of the terminal 6a is joined to the hole 21. At this time, since the step 22 is provided in the upper portion of the hole 21 of the metal layer 2a, even when the terminal 6a is displaced, the terminal 6a is easily guided into the hole 21 and press-fitted to the hole 21. The plating layer 62 of the terminal 6a deforms to fit the recessed-projecting portions 21a, 21b of the hole 21, so that the recessed-projecting portions 62a, 62b fitted to the recessed-projecting portions 21a, 21b of the hole 21 are formed.

The terminal 6a may be firmly fitted to the side surface of the hole 21 by rotating and press-fitting the terminal 6a to the hole 21 at the time when the terminal 6a is press-fitted to the hole 21. Alternatively, the terminal 6a may be press-fitted to the hole 21 without rotating the terminal 6a. The terminal 6a may be firmly fitted to the bottom surface of the hole 21 by rotating the terminal 6a after the lower end of the terminal 6a is in contact with the bottom surface of the hole 21. Similarly to the terminal 6a, the terminals 6b to 6e illustrated in FIG. 1 are joined to respective recessed portions in the metal layers 2a to 2e by press-fitting.

Subsequently, the bonding materials 5, 7, 11 are melted by heating and then solidified by cooling, so that the implant printed circuit board is integrated with the insulating circuit boards (1a, 2a, 2b, 3a), (1b, 2c to 2e, 3b). After that, the semiconductor element 4 is sealed with the sealing resin 9. Hereby, the semiconductor device according to the first embodiment as illustrated in FIG. 1 is completed.

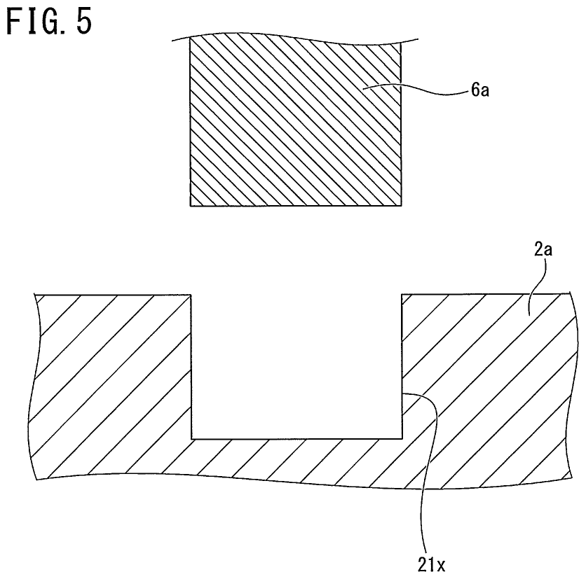

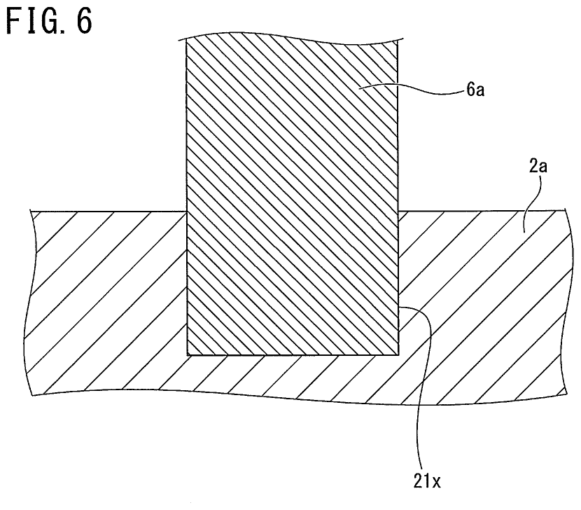

Herein, with reference to FIG. 5 and FIG. 6, a semiconductor device according to a comparative example will be described. FIG. 5 illustrates a state before the terminal 6a is press-fitted to a hole 21x of the metal layer 2a in a manufacturing process of the semiconductor device according to the comparative example. The semiconductor device according to the comparative example is different from the semiconductor device according to the first embodiment illustrated in FIG. 3 in that no step is provided in an upper portion of the hole 21x and in that the hole 21x has a flat bottom surface and a flat side surface, and no recessed-projecting portion is formed intentionally. FIG. 6 illustrates a state after the terminal 6a is press-fitted to the hole 21x of the metal layer 2a in the manufacturing process of the semiconductor device according to the comparative example.

In the semiconductor device according to the comparative example, since the bottom surface and the side surface of the hole 21x are flat, the terminal 6a press-fitted to the hole 21x easily falls out from the hole 21x, so that a long-term reliability decreases. In contrast, in the semiconductor device according to the first embodiment, since the recessed-projecting portions 21a, 21b are intentionally formed in the hole 21, as illustrated in FIG. 2, it is possible to fit the terminal 6a into the recessed-projecting portions 21a, 21b of the hole 21. This can improve the joining strength between the terminal 6a and the metal layer 2a and prevent the terminal 6a from falling out, thereby making it possible to secure a long-term reliability.

Furthermore, in the semiconductor device according to the first embodiment, since the plating layer 62 provided on the surface of the terminal 6a is made of a material softer than that of the metal layer 2a, the plating layer 62 can be easily deformed to be fitted to the recessed-projecting portions 21a, 21b of the hole 21, thereby allowing the terminal 6a to be firmly fitted to the metal layer 2a.

In the semiconductor device according to the comparative example, it is difficult to secure accuracy of position when the terminal 6a is press-fitted to the hole 21x, and it is difficult for the terminal 6a to be press-fitted to the hole 21x. In contrast, in the semiconductor device according to the first embodiment, the step 22 is provided in the upper portion of the hole 21, as illustrated in FIG. 3. This allows the terminal 6a to be guided into the hole 21 even when the terminal 6a is displaced, thereby making it possible to restrain failures at the time of press-fitting of the terminal 6a.

### Second Embodiment

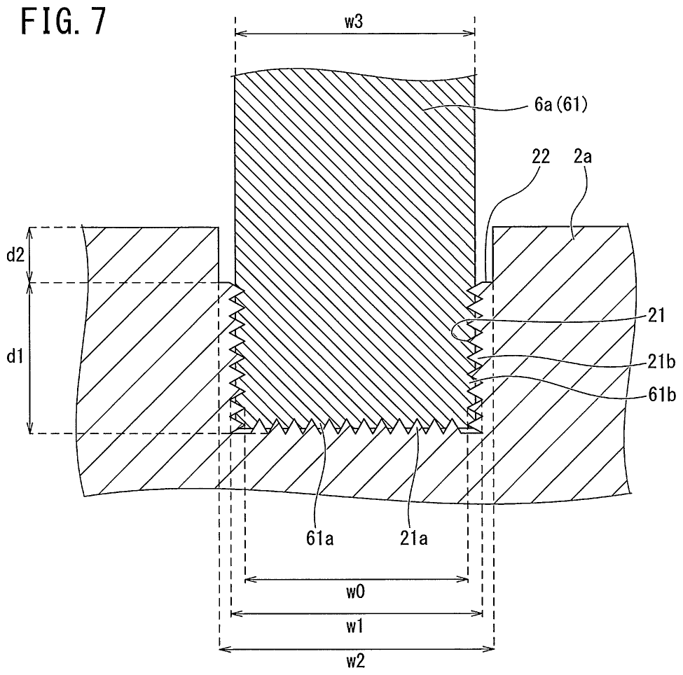

FIG. 7 is a sectional view illustrating a state after the terminal 6a is press-fitted to the hole 21 of the metal layer 2a in a semiconductor device according to a second embodiment, and corresponds to the sectional view of the semiconductor device according to the first embodiment illustrated in FIG. 2. As illustrated in FIG. 7, the semiconductor device according to the second embodiment is different from the semiconductor device according to the first embodiment illustrated in FIG. 2 in that no plating layer is provided on the surface side of the terminal 6a, and the terminal 6a includes only the main body 61.

In the semiconductor device according to the second embodiment, the main body 61 includes no plating layer and is directly in contact with the bottom surface and the side surface of the hole 21. The lower end of the main body 61 has an end surface provided with the recessed-projecting portion 61a deforming to be fitted to the recessed-projecting portion 21a on the bottom surface of the hole 21 at the time when the terminal 6a is press-fitted to the hole 21. The lower end of the main body 61 has an outer peripheral surface provided with the recessed-projecting portion 61b deforming to be fitted to the recessed-projecting portion 21b on the side surface of the hole 21 at the time when the terminal 6a is press-fitted to the hole 21. The other configuration of the semiconductor device according to the second embodiment is similar to the configuration of the semiconductor device according to the first embodiment, and therefore, a redundant description thereof is omitted.

In the semiconductor device according to the second embodiment, the hole 21 includes the recessed-projecting portions 21a, 21b formed intentionally, similarly to the semiconductor device according to the first embodiment. Hereby, the terminal 6a deforms to be fitted to the recessed-projecting portions 21a, 21b, thereby making it possible to prevent the terminal 6a from falling out and to improve the joining strength between the terminal 6a and the metal layer 2a. In addition, the step 22 is provided in the upper portion of the hole 21, thereby making it possible to guide the terminal 6a into the hole 21 and to easily press-fit the terminal 6a to the hole 21.

### Third Embodiment

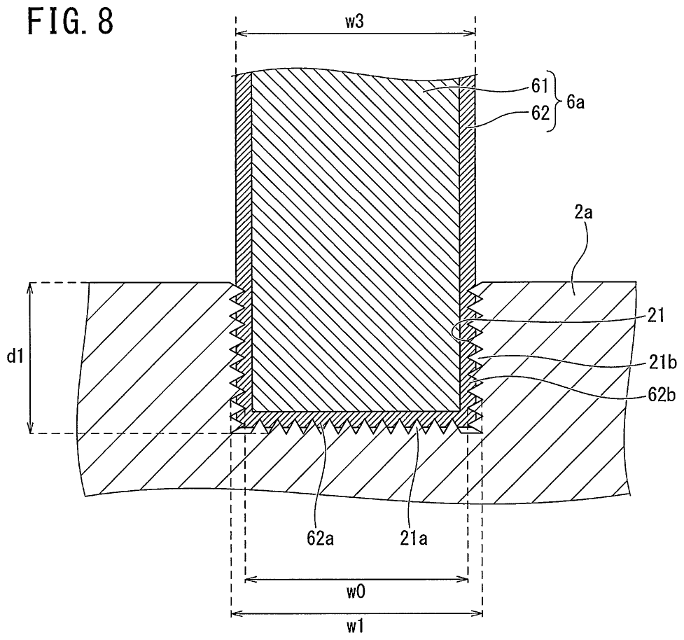

FIG. 8 is a sectional view illustrating a state after the terminal 6a is press-fitted to the hole 21 of the metal layer 2a in a semiconductor device according to a third embodiment, and corresponds to the sectional view of the semiconductor device according to the first embodiment illustrated in FIG. 2. The semiconductor device according to the third embodiment is different from the semiconductor device according to the first embodiment illustrated in FIG. 2 in that no step is provided in the upper portion of the hole 21, as illustrated in FIG. 8. The other configuration of the semiconductor device according to the third embodiment is similar to the configuration of the semiconductor device according to the first embodiment, and therefore, a redundant description thereof is omitted.

In the semiconductor device according to the third embodiment, the hole 21 includes the recessed-projecting portions 21a, 21b formed intentionally, similarly to the semiconductor device according to the first embodiment. Hereby, the terminal 6a deforms to be fitted to the recessed-projecting portions 21a, 21b, thereby making it possible to prevent the terminal 6a from falling out and to improve the joining strength between the terminal 6a and the metal layer 2a.

### Fourth Embodiment

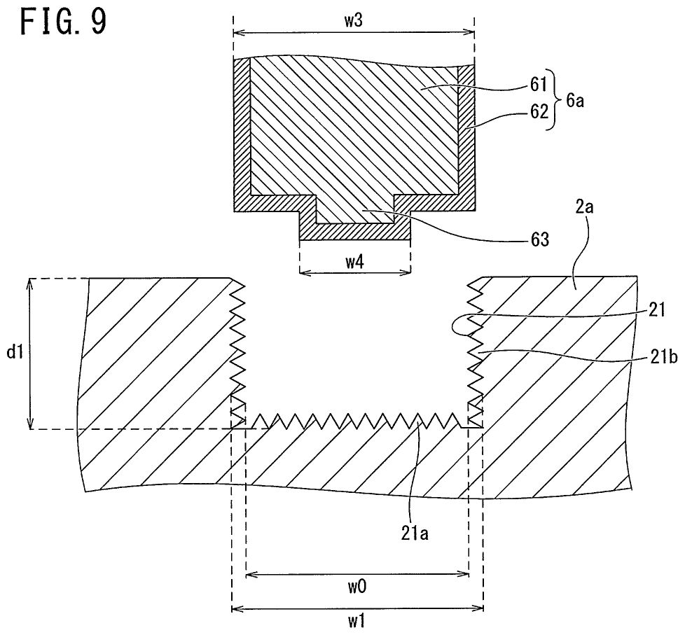

FIG. 9 is a sectional view illustrating a state before the terminal 6a is press-fitted to the hole 21 of the metal layer 2a in a semiconductor device according to a fourth embodiment, and corresponds to the sectional view of the semiconductor device according to the first embodiment illustrated in FIG. 3. The semiconductor device according to the fourth embodiment is different from the semiconductor device according to the first embodiment illustrated in FIG. 3 in that no step is provided in the upper portion of the hole 21 and in that a projecting portion 63 is provided on the lower end of the terminal 6a which is press-fitted to the hole 21, as illustrated in FIG. 9.

The projecting portion 63 has a diameter w4, which is smaller than the diameter w3 before the terminal 6a is press-fitted to the hole 21 and smaller than the diameter w0 of the hole 21. After the terminal 6a is press-fitted to the hole 21 of the metal layer 2a in the semiconductor device according to the fourth embodiment, the semiconductor device according to the fourth embodiment has generally the same section as the semiconductor device according to the third embodiment illustrated in FIG. 8 except that the shape of the projecting portion 63 on the lower end side of the terminal 6a remains. The other configuration of the semiconductor device according to the fourth embodiment is similar to the configuration of the semiconductor device according to the first embodiment, and therefore, a redundant description thereof is omitted.

In the semiconductor device according to the fourth embodiment, the hole 21 includes the recessed-projecting portions 21a, 21b formed intentionally, similarly to the semiconductor device according to the first embodiment. Hereby, the terminal 6a deforms to be fitted to the recessed-projecting portions 21a, 21b, thereby making it possible to prevent the terminal 6a from falling out and to improve the joining strength between the terminal 6a and the metal layer 2a. In addition, in the semiconductor device according to the fourth embodiment, since the projecting portion 63 is provided on the lower end of the terminal 6a, the terminal 6a can be easily press-fitted to the hole 21.

### Fifth Embodiment

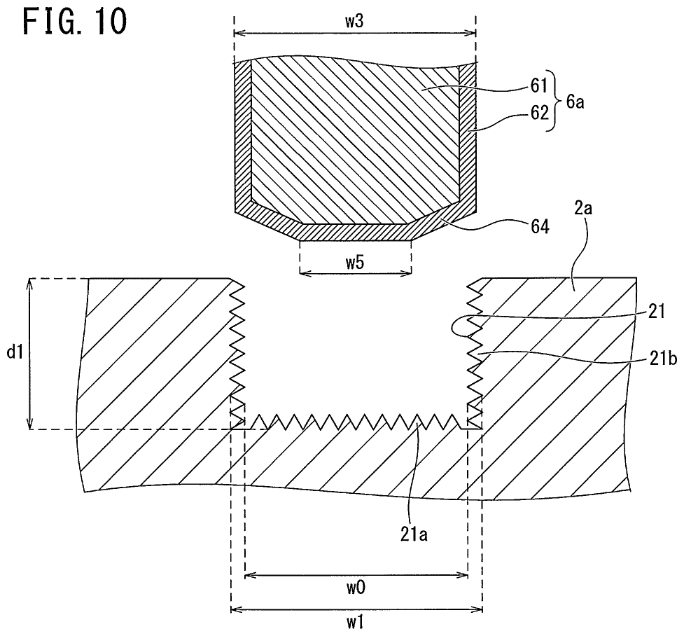

FIG. 10 is a sectional view illustrating a state before the terminal 6a is press-fitted to the hole 21 of the metal layer 2a in a semiconductor device according to a fifth embodiment, and corresponds to the sectional view of the semiconductor device according to the first embodiment illustrated in FIG. 3. The semiconductor device according to the fifth embodiment is different from the semiconductor device according to the first embodiment illustrated in FIG. 3 in that a tapered portion 64 is provided on the lower end side of the terminal 6a which is press-fitted to the hole 21, as illustrated in FIG. 10.

The lower end of the terminal 6a has a diameter w5, which is smaller than the diameter w3 before the terminal 6a is press-fitted to the hole 21 and which is smaller than the diameter w0 of the hole 21. After the terminal 6a is press-fitted to the hole 21 of the metal layer 2a in the semiconductor device according to the fifth embodiment, the semiconductor device according to the fifth embodiment has generally the same section as the semiconductor device according to the third embodiment illustrated in FIG. 8 except that the shape of the tapered portion 64 on the lower end side of the terminal 6a remains. The other configuration of the semiconductor device according to the fifth embodiment is similar to the configuration of the semiconductor device according to the first embodiment, and therefore, a redundant description thereof is omitted.

In the semiconductor device according to the fifth embodiment, the hole 21 includes the recessed-projecting portions 21a, 21b formed intentionally, similarly to the semiconductor device according to the first embodiment. Hereby, the terminal 6a deforms to be fitted to the recessed-projecting portions 21a, 21b, thereby making it possible to prevent the terminal 6a from falling out and to improve the joining strength between the terminal 6a and the metal layer 2a. In addition, in the semiconductor device according to the fifth embodiment, since the tapered portion 64 is provided on the lower end side of the terminal 6a, the terminal 6a can be easily press-fitted to the hole 21.

### Sixth Embodiment

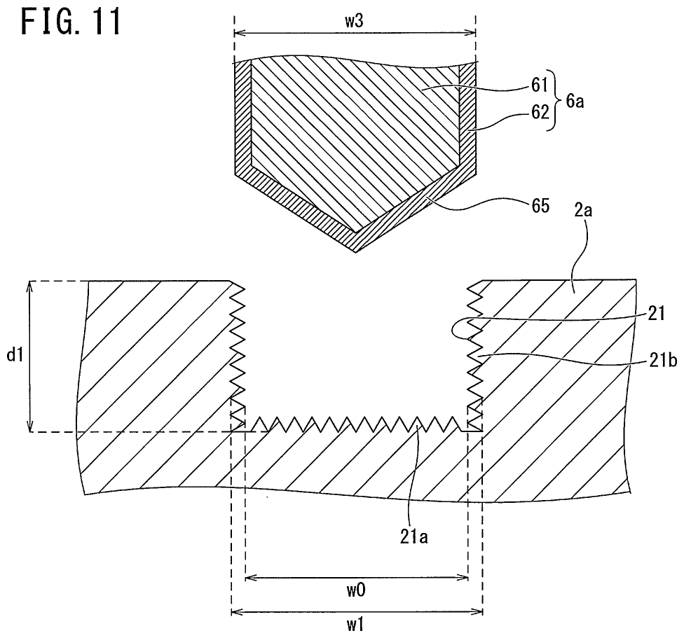

FIG. 11 is a sectional view illustrating a state before the terminal 6a is press-fitted to the hole 21 of the metal layer 2a in a semiconductor device according to a sixth embodiment, and corresponds to the sectional view of the semiconductor device according to the first embodiment illustrated in FIG. 3. The semiconductor device according to the sixth embodiment is different from the semiconductor device according to the first embodiment illustrated in FIG. 3 in that a tapered portion 65 is provided on the lower end side of the terminal 6a which lower end side is press-fitted to the hole 21, as illustrated in FIG. 11.

The lower end side of the terminal 6a has a tapered shape. After the terminal 6a is press-fitted to the hole 21 of the metal layer 2a in the semiconductor device according to the sixth embodiment, the semiconductor device according to the sixth embodiment has generally the same section as the semiconductor device according to the third embodiment illustrated in FIG. 8 except that the shape of the tapered portion 65 on the lower end side of the terminal 6a remains. The other configuration of the semiconductor device according to the sixth embodiment is similar to the configuration of the semiconductor device according to the first embodiment, and therefore, a redundant description thereof is omitted.

In the semiconductor device according to the sixth embodiment, the hole 21 includes the recessed-projecting portions 21a, 21b formed intentionally, similarly to the semiconductor device according to the first embodiment. Hereby, the terminal 6a deforms to be fitted to the recessed-projecting portions 21a, 21b, thereby making it possible to prevent the terminal 6a from falling out and to improve the joining strength between the terminal 6a and the metal layer 2a. In addition, in the semiconductor device according to the sixth embodiment, since the tapered portion 65 is provided on the lower end side of the terminal 6a, the terminal 6a can be easily press-fitted to the hole 21.

### Seventh Embodiment

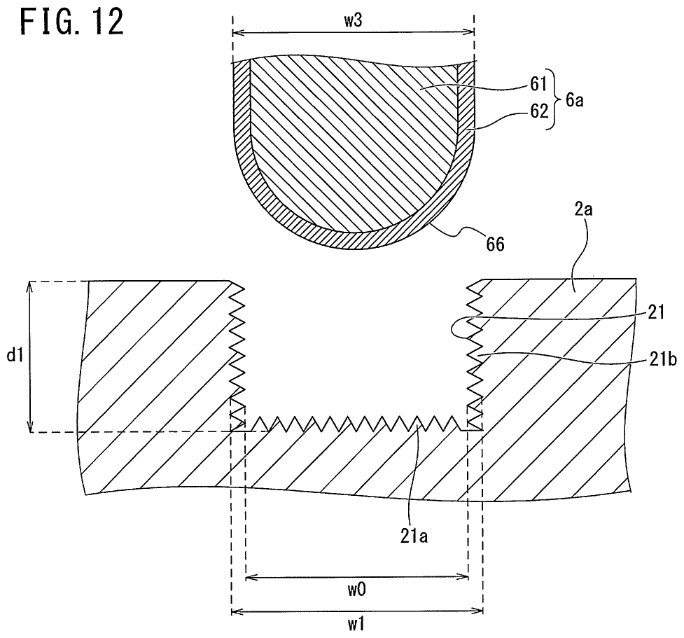

FIG. 12 is a sectional view illustrating a state before the terminal 6a is press-fitted to the hole 21 of the metal layer 2a in a semiconductor device according to a seventh embodiment, and corresponds to the sectional view of the semiconductor device according to the first embodiment illustrated in FIG. 3. The semiconductor device according to the seventh embodiment is different from the semiconductor device according to the first embodiment illustrated in FIG. 3 in that the lower end side of the terminal 6a which is press-fitted to the hole 21 has a curved surface 66, as illustrated in FIG. 12.

After the terminal 6a is press-fitted to the hole 21 of the metal layer 2a in the semiconductor device according to the seventh embodiment, the semiconductor device according to the seventh embodiment has generally the same section as the semiconductor device according to the third embodiment illustrated in FIG. 8 except that the curved surface 66 on the lower end side of the terminal 6a remains. The other configuration of the semiconductor device according to the seventh embodiment is similar to the configuration of the semiconductor device according to the first embodiment, and therefore, a redundant description thereof is omitted.

In the semiconductor device according to the seventh embodiment, the hole 21 includes the recessed-projecting portions 21a, 21b formed intentionally, similarly to the semiconductor device according to the first embodiment. Hereby, the terminal 6a deforms to be fitted to the recessed-projecting portions 21a, 21b, thereby making it possible to prevent the terminal 6a from falling out and to improve the joining strength between the terminal 6a and the metal layer 2a. In addition, in the semiconductor device according to the seventh embodiment, since the lower end side of the terminal 6a has the curved surface 66, the terminal 6a can be easily press-fitted to the hole 21.

### Eighth Embodiment

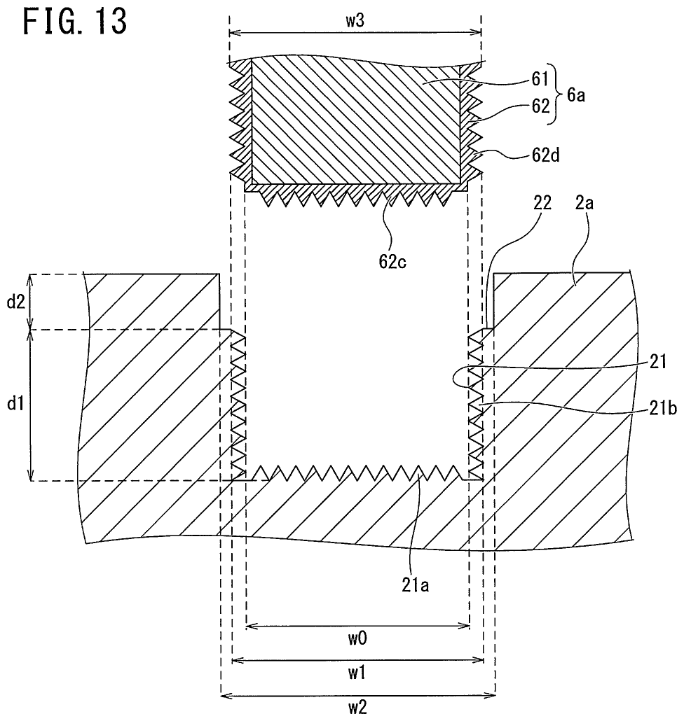

FIG. 13 is a sectional view illustrating a state before the terminal 6a is press-fitted to the hole 21 of the metal layer 2a in a semiconductor device according to an eighth embodiment, and corresponds to the sectional view of the semiconductor device according to the first embodiment illustrated in FIG. 3. The semiconductor device according to the eighth embodiment is different from the semiconductor device according to the first embodiment illustrated in FIG. 3 in that recessed-projecting portions 62c, 62d are formed intentionally in at least the portion of the terminal 6a which is inserted into the hole 21, as illustrated in FIG. 13.

The diameter w3 of the terminal 6a corresponds to an outer-side virtual outer peripheral surface in contact with the projections of the recessed-projecting portion 62d of the terminal 6a and is larger than the diameter w0 of the hole 21. The diameter w3 of the terminal 6a is generally the same as the diameter w1 of the outer-side virtual inner peripheral surface in contact with the recesses of the recessed-projecting portion 21b on the side surface of the hole 21 or is smaller than the diameter w1. The recessed-projecting portion 62c is formed on the plating layer 62 on the end surface of the lower end of the terminal 6a, and the recessed-projecting portion 62d is formed on the plating layer 62 on the outer peripheral surface of the lower end of the terminal 6a. The recessed-projecting portions 62c, 62d are formable by roughing the surface of the plating layer 62 by laser application, for example. The arithmetic average roughness (Ra) of the recessed-projecting portions 62c, 62d is about 2 μm or more but 150 μm or less, for example. In the semiconductor device according to the eighth embodiment, the material of the plating layer 62 may be the same as the material of the metal layer 2a, may be harder than the material of the metal layer 2a, or may be softer than the material of the metal layer 2a.

Note that only one of the recessed-projecting portions 62c, 62d on the plating layer 62 may be formed. In a case where the terminal 6a does not include the plating layer 62 but includes only the main body 61, recessed-projecting portions may be formed intentionally on the end surface and the outer peripheral surface of the lower end of the main body 61.

At the time when the terminal 6a is inserted into the hole 21, the terminal 6a is rotated and inserted into the hole 21, so that the recessed-projecting portion 62d on the outer peripheral surface of the terminal 6a can be easily fitted to the recessed-projecting portion 21b on the side surface of the hole 21. Note that the terminal 6a may be press-fitted to the hole 21 without rotating the terminal 6a.

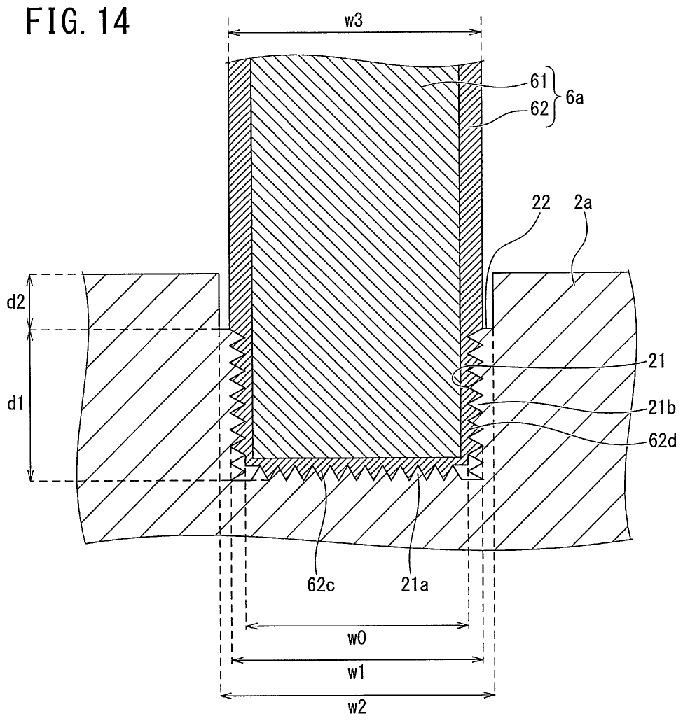

FIG. 14 is a sectional view illustrating a state after the terminal 6a is press-fitted to the hole 21 of the metal layer 2a in the semiconductor device according to the eighth embodiment, and corresponds to the sectional view of the semiconductor device according to the first embodiment illustrated in FIG. 2. The recessed-projecting portion 62c on the end surface of the terminal 6a is fitted to the recessed-projecting portion 21a on the bottom surface of the hole 21, and the recessed-projecting portion 62d on the outer peripheral surface of the terminal 6a is fitted to the recessed-projecting portion 21b on the side surface of the hole 21. The other configuration of the semiconductor device according to the eighth embodiment is similar to the configuration of the semiconductor device according to the first embodiment, and therefore, a redundant description thereof is omitted.

In the semiconductor device according to the eighth embodiment, the hole 21 includes the recessed-projecting portions 21a, 21b formed intentionally, similarly to the semiconductor device according to the first embodiment. Hereby, the terminal 6a deforms to be fitted to the recessed-projecting portions 21a, 21b, thereby making it possible to prevent the terminal 6a from falling out and to improve the joining strength between the terminal 6a and the metal layer 2a. In addition, the step 22 is provided in the upper portion of the hole 21, thereby making it possible to guide the terminal 6a into the hole 21 and to easily press-fit the terminal 6a to the hole 21.

Besides, in the semiconductor device according to the eighth embodiment, the recessed-projecting portions 62c, 62d are also formed intentionally in the terminal 6a in advance before the terminal 6a is press-fitted to the hole 21 of the metal layer 2a. Hereby, the recessed-projecting portions 62c, 62d of the terminal 6a are fitted to the recessed-projecting portions 21a, 21b of the hole 21, thereby allowing the terminal 6a to be more firmly joined to the metal layer 2a.

### Ninth Embodiment

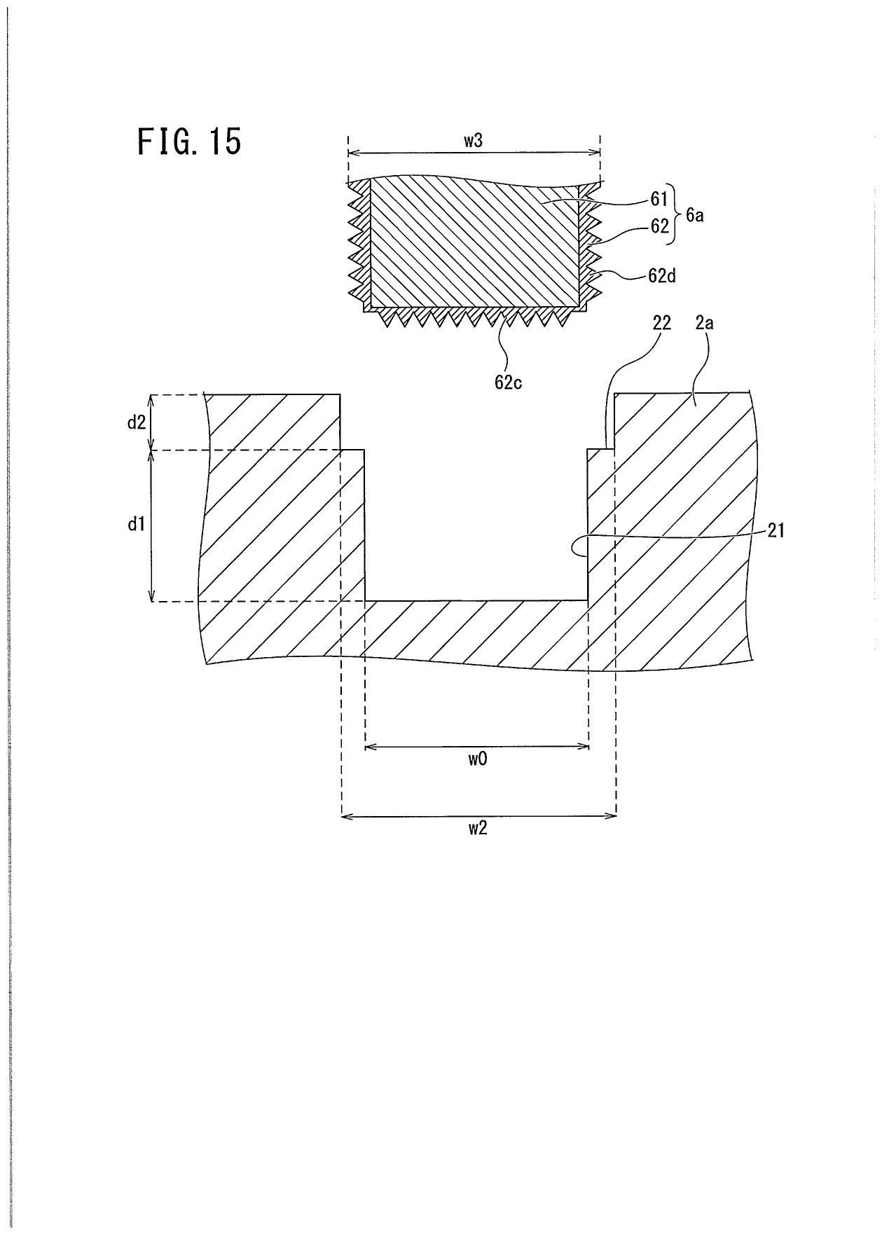

FIG. 15 is a sectional view illustrating a state before the terminal 6a is press-fitted to the hole 21 of the metal layer 2a in a semiconductor device according to a ninth embodiment, and corresponds to the sectional view of the semiconductor device according to the first embodiment illustrated in FIG. 3. As illustrated in FIG. 15, the semiconductor device according to the ninth embodiment is different from the semiconductor device according to the first embodiment illustrated in FIG. 3 in that recessed-projecting portions 62c, 62d are formed intentionally in at least the portion of the terminal 6a which is inserted into the hole 21 and in that no recessed-projecting portion is formed intentionally in the hole 21, and the hole 21 as a flat bottom surface and a flat side surface.

The diameter w3 of the terminal 6a corresponds to an outer-side virtual outer peripheral surface in contact with the projections of the recessed-projecting portion 62d of the terminal 6a and is larger than the diameter w0 of the hole 21. The recessed-projecting portion 62c is formed on the plating layer 62 on the end surface of the lower end of the terminal 6a, and the recessed-projecting portion 62d is formed on the plating layer 62 on the outer peripheral surface of the lower end of the terminal 6a. The configuration of the terminal 6a is similar to that of the terminal 6a of the semiconductor device according to the eighth embodiment illustrated in FIG. 13, and therefore, a redundant description thereof is omitted. Note that, in the ninth embodiment, the material of the plating layer 62 is harder than the material of the metal layer 2a. For example, the metal layer 2a may be made of Cu, and the plating layer 62 may be made of Ni.

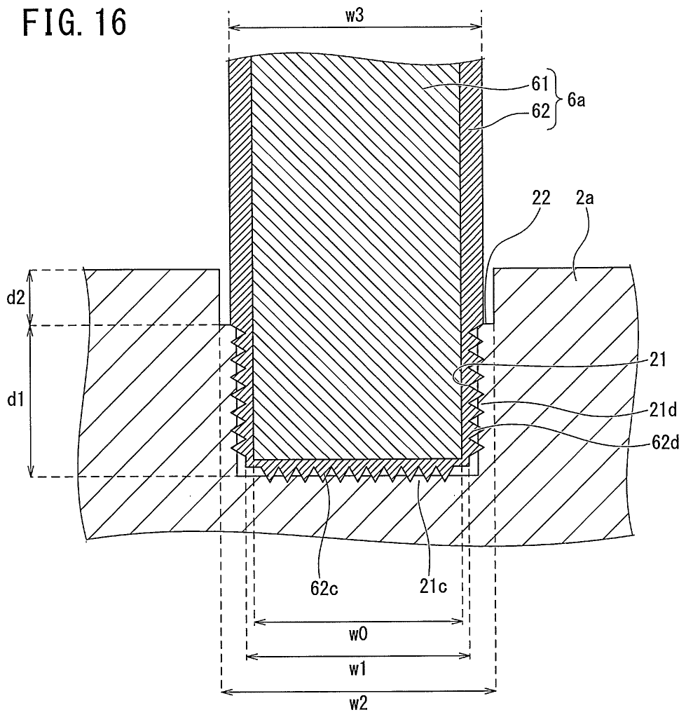

In a manufacturing method for manufacturing the semiconductor device according to the eighth embodiment, the terminal 6a including the recessed-projecting portions 62c, 62d formed intentionally in advance is prepared, as illustrated in FIG. 15. In addition, an insulating circuit board including the metal layer 2a having the hole 21 with a flat bottom surface and a flat side surface is prepared. Then, as illustrated in FIG. 16, the bottom surface and the side surface of the hole 21 are deformed by the recessed-projecting portions 62c, 62d of the terminal 6a by press-fitting the terminal 6a to the hole 21, so that recessed-projecting portions 21c, 21d are formed intentionally in the hole 21. The recessed-projecting portion 62c on the end surface of the terminal 6a is fitted to the recessed-projecting portion 21c on the bottom surface of the hole 21. The recessed-projecting portion 62d on the outer peripheral surface of the terminal 6a is fitted to the recessed-projecting portion 21d on the side surface of the hole 21.

When the terminal 6a is rotated and press-fitted to the hole 21 at the time when the terminal 6a is press-fitted to the hole 21, the recessed-projecting portion 21d is easily formed on the side surface of the hole 21. When the terminal 6a is rotated after the terminal 6a is in contact with the bottom surface of the hole 21, the recessed-projecting portion 21c is easily formed on the bottom surface of the hole 21. The other configuration of the semiconductor device according to the ninth embodiment is similar to the configuration of the semiconductor device according to the first embodiment, and therefore, a redundant description thereof is omitted.

In the semiconductor device according to the ninth embodiment, the hole 21 includes the recessed-projecting portions 21c, 21d formed intentionally, similarly to the semiconductor device according to the first embodiment. This makes it possible to prevent the terminal 6a from falling out and to improve the joining strength between the terminal 6a and the metal layer 2a. In addition, the step 22 is provided in the upper portion of the hole 21, thereby making it possible to guide the terminal 6a into the hole 21 and to easily press-fit the terminal 6a to the hole 21.

Besides, in the semiconductor device according to the ninth embodiment, the recessed-projecting portions 62c, 62d are formed intentionally in the terminal 6a in advance before the terminal 6a is press-fitted to the hole 21 of the metal layer 2a. Hereby, even in a case where no recessed-projecting portion is formed intentionally in the hole 21, the recessed-projecting portions 21c, 21d can be formed by deforming the bottom surface and the side surface of the hole 21 at the time when the terminal 6a is press-fitted to the hole 21. In addition, with the use of the plating layer 62 harder than the metal layer 2a, the metal layer 2a is easily deformed at the time when the terminal 6a is press-fitted to the hole 21, thereby allowing the recessed-projecting portions 21c, 21d to be easily formed in the hole 21.

### Tenth Embodiment

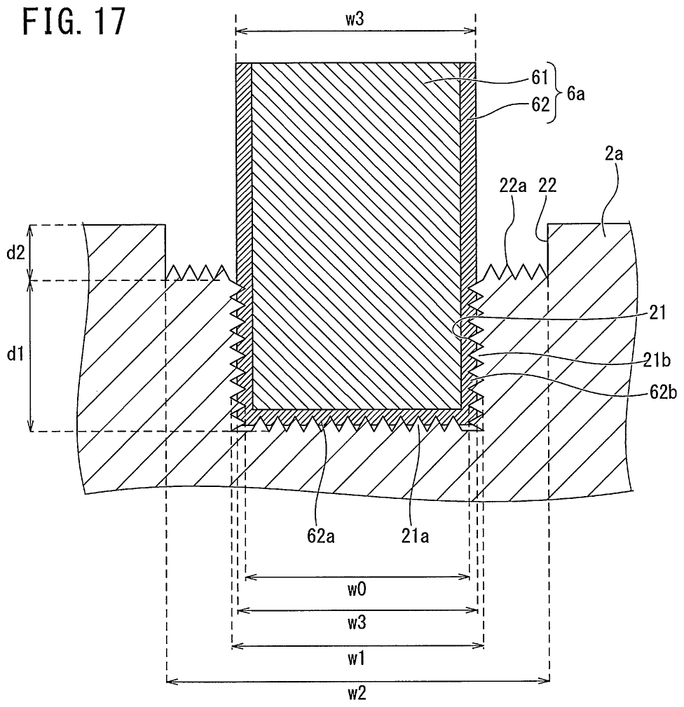

FIG. 17 is a sectional view illustrating a state after the terminal 6a is press-fitted to the hole 21 of the metal layer 2a in a semiconductor device according to a tenth embodiment, and corresponds to the sectional view of the semiconductor device according to the first embodiment illustrated in FIG. 2. The semiconductor device according to the tenth embodiment is different from the semiconductor device according to the first embodiment illustrated in FIG. 2 in that the recessed-projecting portion 22a is formed intentionally on the bottom surface of the step 22, as illustrated in FIG. 17.

The arithmetic average roughness (Ra) of the recessed-projecting portion 22a of the step 22 is about 2 μm or more but 150 μm or less, for example. A formation method of the recessed-projecting portion 22a in the step 22 is similar to the formation method of the recessed-projecting portion 21a in the hole 21. The other configuration of the semiconductor device according to the tenth embodiment is similar to the configuration of the semiconductor device according to the first embodiment, and therefore, a redundant description thereof is omitted.

In the semiconductor device according to the tenth embodiment, the hole 21 includes the recessed-projecting portions 21a, 21b formed intentionally, similarly to the semiconductor device according to the first embodiment. Hereby, the terminal 6a deforms to be fitted to the recessed-projecting portions 21a, 21b, thereby making it possible to prevent the terminal 6a from falling out and to improve the joining strength between the terminal 6a and the metal layer 2a. In addition, the step 22 is provided in the upper portion of the hole 21, thereby making it possible to guide the terminal 6a into the hole 21 and to easily press-fit the terminal 6a to the hole 21.

Besides, in the semiconductor device according to the tenth embodiment, the recessed-projecting portion 22a is formed intentionally on the bottom surface of the step 22, and hereby, in a case where the diameter w3 of the terminal 6a becomes wide in the vicinity of the portion of the terminal 6a which is inserted into the hole 21, the terminal 6a is fitted to the recessed-projecting portion 22a on the bottom surface of the step 22, thereby allowing the terminal 6a to be further firmly joined to the metal layer 2a.

### Eleventh Embodiment

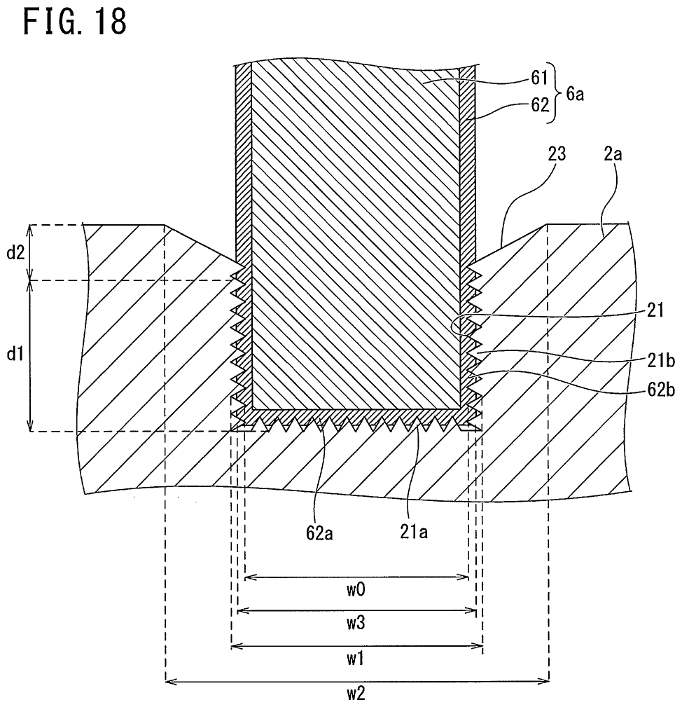

FIG. 18 is a sectional view illustrating a state after the terminal 6a is press-fitted to the hole 21 of the metal layer 2a in a semiconductor device according to an eleventh embodiment, and corresponds to the sectional view of the semiconductor device according to the first embodiment illustrated in FIG. 2. The semiconductor device according to the eleventh embodiment is different from the semiconductor device according to the first embodiment illustrated in FIG. 2 in that a tapered portion 23 is provided in the upper portion of the hole 21 instead of providing a step in the upper portion of the hole 21, as illustrated in FIG. 18. The other configuration of the semiconductor device according to the eleventh embodiment is similar to that of the semiconductor device according to the first embodiment, and therefore, a redundant description thereof is omitted.

In the semiconductor device according to the eleventh embodiment, the hole 21 includes the recessed-projecting portions 21a, 21b formed intentionally, similarly to the semiconductor device according to the first embodiment. Hereby, the terminal 6a deforms to be fitted to the recessed-projecting portions 21a, 21b, thereby making it possible to prevent the terminal 6a from falling out and to improve the joining strength between the terminal 6a and the metal layer 2a. In addition, the tapered portion 23 is provided in the upper portion of the hole 21, thereby making it possible to guide the terminal 6a into the hole 21 and to easily press-fit the terminal 6a to the hole 21.

### Twelfth Embodiment

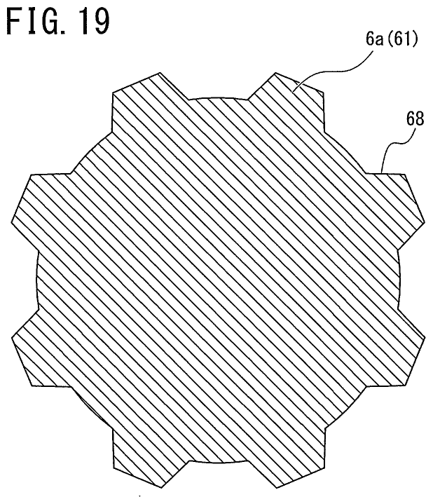

FIG. 19 is a sectional view of a section of the portion of the terminal 6a which is inserted into the hole 21 in a semiconductor device according to a twelfth embodiment, the section being taken along a vertical direction to an axial direction (a longitudinal direction) of the terminal 6a. The semiconductor device according to the twelfth embodiment is different from the semiconductor device according to the first embodiment illustrated in FIG. 2 in that a plurality of slits (grooves) 68 is provided in at least the portion of the terminal 6a which is inserted into the hole 21, as illustrated in FIG. 19.

The plurality of slits 68 is provided on an outer peripheral side of the terminal 6a and extends in parallel to the axial direction of the terminal 6a. The interval between the slits 68, the number of the slits 68, or the depth, length, or width of the slits 68 is not particularly limited. Note that the slits 68 may be provided diagonally (spirally) to the axial direction of the terminal 6a or may be provided vertically to the axial direction of the terminal 6a. The other configuration of the semiconductor device according to the twelfth embodiment is similar to that of the semiconductor device according to the first embodiment, and therefore, a redundant description thereof is omitted.

In the semiconductor device according to the twelfth embodiment, the hole 21 includes the recessed-projecting portions 21a, 21b formed intentionally, similarly to the semiconductor device according to the first embodiment. Hereby, the terminal 6a is fitted to the recessed-projecting portions 21a, 21b, thereby making it possible to prevent the terminal 6a from falling out and to improve the joining strength between the terminal 6a and the metal layer 2a. In addition, the step 22 is provided in the upper portion of the hole 21, thereby making it possible to guide the terminal 6a into the hole 21 and to easily press-fit the terminal 6a to the hole 21.

Besides, in the semiconductor device according to the twelfth embodiment, since the terminal 6a includes the slits 68, the contact area of the outer peripheral surface of the terminal 6a to be fitted to the recessed-projecting portion 21b of the hole 21 increases, thereby allowing the terminal 6a to be more firmly joined to the metal layer 2a.

### Thirteenth Embodiment

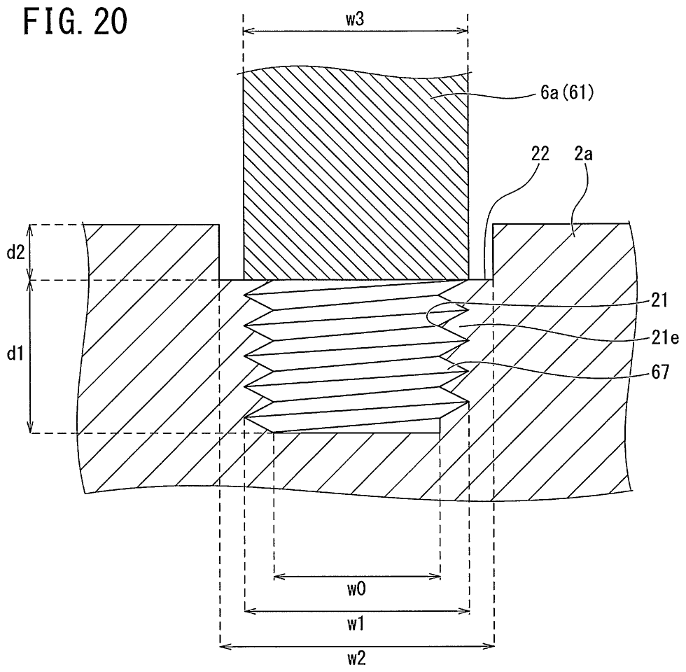

FIG. 20 is a sectional view illustrating a state after the terminal 6a is inserted into the hole 21 of the metal layer 2a in a semiconductor device according to a thirteenth embodiment, and corresponds to the sectional view of the semiconductor device according to the first embodiment illustrated in FIG. 2. The semiconductor device according to the twelfth embodiment is different from the semiconductor device according to the first embodiment illustrated in FIG. 2 in that at least the portion of the terminal 6a which is inserted into the hole 21 is a screw thread (external thread) 67, as illustrated in FIG. 20.

A recessed-projecting portion (internal thread) 21e corresponding to the external thread 67 of the terminal 6a is formed on the side surface of the hole 21. The bottom surface of the hole 21 is flat but may include a recessed-projecting portion. The internal thread 21e is formed intentionally in advance before the terminal 6a is inserted into the hole 21 of the metal layer 2a. At the time when the terminal 6a is inserted into the hole 21 of the metal layer 2a, the terminal 6a may be fitted to the metal layer 2a such that the external thread 67 of the terminal 6a is fastened with the internal thread 21e on the side surface of the hole 21.

Note that no internal thread may be formed on the side surface of the hole 21 in advance before the terminal 6a is inserted into the hole 21 of the metal layer 2a. In this case, the internal thread 21e may be formed intentionally such that the terminal 6a is screwed and press-fitted to the hole 21 to deform the side surface of the hole 21 at the time when the terminal 6a is inserted into the hole 21 of the metal layer 2a. A plating layer harder than the metal layer 2a may be formed on the surface of the external thread 67 of the terminal 6a. The other configuration of the semiconductor device according to the thirteenth embodiment is similar to the configuration of the semiconductor device according to the first embodiment, and therefore, a redundant description thereof is omitted.

In the semiconductor device according to the thirteenth embodiment, the hole 21 includes the recessed-projecting portion (internal thread) 21e formed intentionally, similarly to the semiconductor device according to the first embodiment. Hereby, the terminal 6a is fitted to the recessed-projecting portions 21e, thereby making it possible to prevent the terminal 6a from falling out and to improve the joining strength between the terminal 6a and the metal layer 2a. In addition, the step 22 is provided in the upper portion of the hole 21, thereby making it possible to guide the terminal 6a into the hole 21 and to easily press-fit the terminal 6a to the hole 21.

Besides, in the semiconductor device according to the thirteenth embodiment, at least the portion of the terminal 6a which is inserted into the hole 21 is the screw thread (external thread) 67, so that the portion of the terminal 6a can be fastened with the recessed-projecting portion (internal thread) 21e of the hole 21 and can be firmly joined thereto.

### Other Embodiments

As described above, the invention has been described according to the first to thirteenth embodiments, but it should not be understood that the description and drawings implementing a portion of this disclosure limit the invention. Various alternative embodiments of the present disclosure, examples, and operational techniques will be apparent to those skilled in the art from this disclosure.

For example, the first to thirteenth embodiments deal with a case where the terminal 6a is an external connection terminal, as illustrated in FIG. 1, but the terminal 6a is not limited to an external connection terminal. For example, instead of joining the second implant pin 10b illustrated in FIG. 1 to the metal layer 2a to 2e with the bonding material 11, a hole including a recessed-projecting portion may be provided in a joined portion of the metal layer 2a to 2e with the second implant pin 10b, and the second implant pin 10b may be press-fitted to the hole of the metal layer 2a to 2e.

The first to thirteenth embodiments deal with a semiconductor module using the printed circuit board 8, as illustrated in FIG. 1, but the present disclosure is not limited to this. For example, the present disclosure is also applicable to a semiconductor module conductively connected by a bonding wire without the use of the printed circuit board 8.

The first to thirteenth embodiments deal with a case where the metal layer 2a to which the terminal 6a is joined is an element of the insulating circuit board (1a, 2a, 2b, 3a), but the present disclosure is not limited to this. For example, the metal layer 2a may be a lead frame, a lead, or the like.

Further, the configurations disclosed in the embodiments may be combined as appropriate within a range that does not contradict with the scope of the first and thirteenth embodiments. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising:
a metal layer including a top surface having a hole including a recessed-projecting portion constituted by recesses and projections continuously formed on a surface of the hole; and
a terminal having one end inserted into the hole and extending upward from the top surface of the metal layer.

2. The semiconductor device according to claim 1, wherein the recessed-projecting portion is provided on a side surface of the hole.

3. The semiconductor device according to claim 1, wherein the recessed-projecting portion is provided on a bottom surface of the hole.

4. The semiconductor device according to claim 1, wherein the one end of the terminal has a shape fitted to the recessed-projecting portion.

5. The semiconductor device according to claim 1, wherein a plating layer softer than the metal layer is provided on a surface side of the terminal.

6. The semiconductor device according to claim 1, wherein a plating layer harder than the metal layer is provided on a surface side of the terminal.

7. The semiconductor device according to claim 1, wherein the recessed-projecting portion is a screw thread.

8. The semiconductor device according to claim 1, wherein the hole has an upper portion including a step.

9. The semiconductor device according to claim 8, wherein the step has a bottom surface including a recessed-projecting portion.

10. The semiconductor device according to claim 1, wherein the hole has an upper portion including a tapered portion.

11. The semiconductor device according to claim 1, comprising an insulating circuit board including the metal layer provided on a top surface side of an insulating substrate.

12. The semiconductor device according to claim 11, wherein the insulating circuit board is a DCB substrate.

13. A method for manufacturing a semiconductor device comprising:
preparing a metal layer having a hole including a recessed-projecting portion constituted by recesses and projections continuously formed on a surface of the hole;
preparing a terminal; and
joining the terminal to the metal layer by inserting one end of the terminal into the hole.

14. A method for manufacturing a semiconductor device comprising:
preparing a metal layer having a hole;
preparing a terminal including a recessed-projecting portion constituted by recesses and projections formed continuously on a surface of at least one end of the terminal; and
joining the terminal to the metal layer by inserting, into the hole, the one end of the terminal including the recessed-projecting portion.

15. The method for manufacturing the semiconductor device according to claim 13, wherein
in the preparing of the terminal, the terminal thus prepared has a diameter larger than a diameter of the hole, and
in the joining of the terminal to the metal layer, the terminal is press-fitted to the hole.

16. The method for manufacturing the semiconductor device according to claim 13, wherein a plating layer softer than the metal layer is provided on the one end of the terminal.

17. The method for manufacturing the semiconductor device according to claim 14, wherein a plating layer harder than the metal layer is provided on the one end of the terminal.

18. The method for manufacturing the semiconductor device according to claim 13, wherein in the preparing of the terminal, at least the one end of the terminal thus prepared includes a recessed-projecting portion.

19. The method for manufacturing the semiconductor device according to claim 18, wherein
the recessed-projecting portion of the terminal and the recessed-projecting portion of the hole are screw threads, and
in the joining of the terminal to the metal layer, the screw thread of the terminal is fastened with the screw thread of the hole.

20. The method for manufacturing the semiconductor device according to claim 13, wherein the hole of the metal layer has an upper portion including a step.

21. The method for manufacturing the semiconductor device according to claim 13, wherein in the preparing of the terminal, the one end of the terminal thus prepared includes a step.

22. The method for manufacturing the semiconductor device according to claim 13, wherein in the preparing of the terminal, the one end of the terminal includes a tapered portion.

23. The method for manufacturing the semiconductor device according to claim 13, wherein in the preparing of the terminal, the one end of the terminal has a curved surface.
